(19) United States
(12) Patent Application Publication
(10) Pub. No.: US 2009/0127021 A1
(43) Pub. Date: May 21, 2009

(54) SPEAKER SET AND PORTABLE ELECTRONIC DEVICE INCORPORATING SAME

(75) Inventor: CHEN-FA TING, Tu-Cheng (TW)

Correspondence Address: PCE INDUSTRY, INC.;ATT. Steven Reiss, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 12/039,042

(22) Filed: Feb. 28, 2008

(30) Foreign Application Priority Data
Nov. 20, 2007 (CN) 200710202605.9

(51) Int. Cl. H05K 5/00

(52) U.S. Cl. 181/148

(57) ABSTRACT

A portable electronic device (200) includes a casing (20) containing a speaker set (30) therein and defines a vent (232) therein. The speaker set includes a hollow shell (40) having a first partition wall (451), and a loudspeaker (50). The first partition wall divides an inner space of the shell into a first resonance chamber (47) and a second resonance chamber (49). The first resonance chamber communicates with the second resonance chamber via a communicating port (452). The second chamber communicates with a surrounding environment via a sound propagation port (432) defined in the shell. The sound propagation port communicates with the vent of the casing. The loudspeaker is accommodated in the shell, and acoustically couples with the first resonance chamber.

### BACKGROUND

1. Technical Field

The present invention relates generally to sound emitting devices, particularly to speaker sets and portable electronic devices using the speaker sets.

2. Description of the Related Art

Portable electronic devices, such as mobile phones, CD players, MP3 players, personal digital assistants (PDAs) and the like, have decreased both in size and weight over the past few years and are becoming ever more popular with travelers. This demand for smaller size with ever-increasing capability has required a tremendous effort to continually shrink many of the components contained within the device.

In another aspect, portable electronic devices being designed today require multi-media features and provide the user with the same enjoyable experience as that experienced with conventional high quality desktop systems. Thus, the sounds emanating from a portable electronic device should provide as full a harmonic content as the original sounds. The production of high frequency sounds requires a large acoustic chamber for the movement of a large mass of air. As the device is reduced in size, the size of the acoustic chamber of the speaker set and the maximum power the speaker can handle are also accordingly reduced, resulting in both a reduction in loudness as well as a poorer overall quality of sound.

For example, as shown in FIG. 1, a mobile phone 100 includes a housing 10 and a speaker 19 incorporated in the housing 10. The housing 10 has a top surface 11, a sidewall 13 extending upwards from the top surface 11, and a cavity 15 defined between the top surface 11 and the sidewall 13. A plurality of sound propagation holes 110 is defined in the top surface 11, and communicates with the cavity 15. The speaker 19 has a sound emanating surface 191. The speaker 19 is received in the cavity 15, with the sound emanating surface 191 thereof facing towards the top surface 11. An acoustic chamber is thus formed by the sound emanating surface 191 of the speaker 19 and the housing 10. Since the sound emanating surface 191 of the speaker 19 is disposed close to the top surface 11 of the housing 10, the acoustic chamber is small.

However, increasing the device size to increase the size of the acoustic chamber for the speaker is very undesirable since it would strongly detract from the very characteristics that have helped to make these devices popular, namely size and weight. Thus the size of the device is at odds with high capability sounds of the speaker.

Therefore, an improved speaker set and an improved portable electronic device are desired in order to overcome the above-described problems.

### SUMMARY

A speaker set configured for a portable electronic device is provided in one aspect thereof. The speaker set includes a hollow shell and a loudspeaker. The hollow shell includes a first partition wall dividing an inner space of the shell into a first resonance chamber and a second resonance chamber. The first resonance chamber acoustically communicates with the second resonance chamber via a communicating port defined in the first partition wall. The second chamber acoustically communicates with a surrounding environment via a sound propagation port defined in the shell. The loudspeaker is accommodated in the shell, and acoustically couples with the first resonance chamber. Sounds emanated from the loudspeaker can travel through the first resonance chamber, the communicating port, the second chamber, the sound propagation port and finally into surrounding environment.

Other advantages and novel features will become more apparent from the following detailed description when taken in conjunction with the accompanying drawings.

### BRIEF DESCRIPTION OF THE DRAWINGS

Many aspects of the present speaker set for portable electronic device can be better understood with reference to the following drawings. The components in the drawings are not necessarily drawn to scale, the emphasis instead being placed upon clearly illustrating the principles of the present speaker set and its potential applications. Moreover, in the drawings, like reference numerals designate corresponding parts throughout the several views.

FIG. 1 shows a schematic, cross-sectional view of a typical speaker used in a mobile phone.

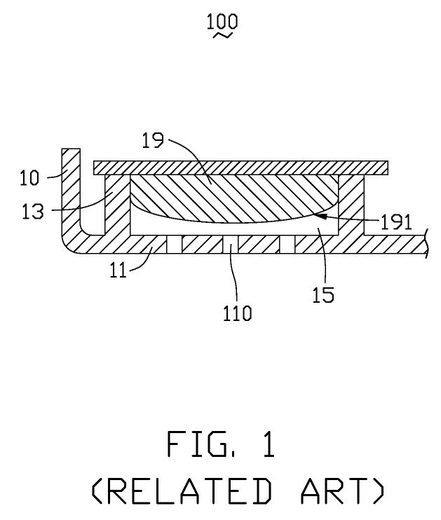

FIG. 2 is a schematic, isometric view of a mobile phone incorporating a speaker set according to a present embodiment.

FIG. 3 shows a schematic, isometric view of the speaker set of FIG. 2.

FIG. 4 shows a disassembled view of the speaker set of FIG. 3.

FIG. 5 shows a cross-sectional view of the speaker set, taken along line V-V of FIG. 3.

### DETAILED DESCRIPTION OF THE PREFERRED EMBODIMENT

The present speaker set is particularly suitable for portable electronic devices, such as mobile phones, PDAs, and the like.

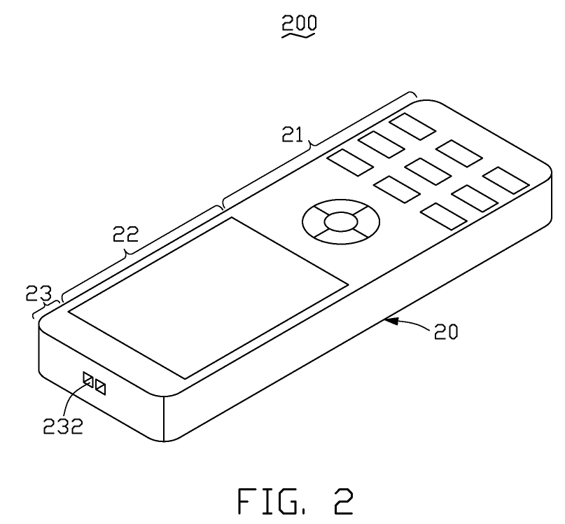

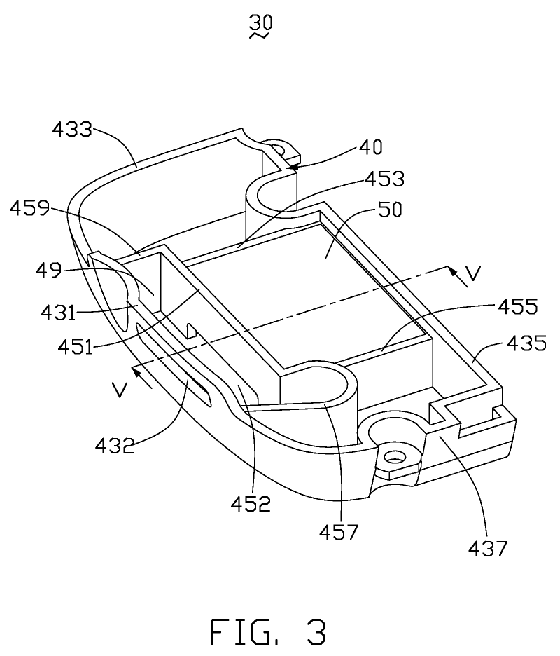

Referring to FIG. 2, a mobile phone 200 incorporating a speaker set 30 (shown in FIG. 3) therein according to the present invention is shown. The mobile phone 200 includes a hollow casing 20 and a variety of elements enclosed in the casing 20. The casing 20 is substantially rectangular shaped in profile, and includes a keypad 21, a display panel 22, and a speaker section 23 respectively disposed at bottom, middle and top portions of the casing 20. The casing 20 defines two vents 232 at one side of the speaker section 23. The vent 232 can be, but is not limited to, a hole, a slot, a slit, a groove, and a notch.

Referring to FIGS. 2 and 3, a speaker set 30 is configured (i.e., arranged and structured) to be disposed in the speaker section 23 of the casing 20, and includes a hollow shell 40 and a loudspeaker 50 accommodated in the shell 40.

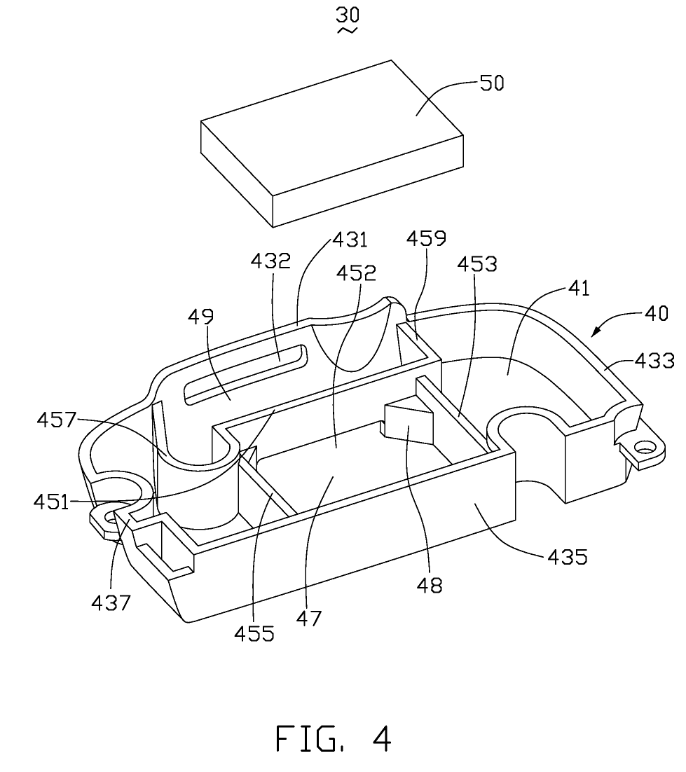

Referring to FIG. 4, the shell 40 of the speaker set 30 is open on one side, and includes a base wall 41, a plurality of sidewalls, i.e. a first sidewall 431, a second sidewall 433, a third sidewall 435, and a fourth sidewall 437, approximately perpendicularly and upwardly extending from a periphery of the base wall 41, a plurality of partition walls, i.e. a first partition wall 451, a second partition wall 453, a third partition wall 455, a fourth partition wall 457, and a fifth partition wall 459, perpendicularly and upwardly extending from a middle portion of the base wall 41, and a supporting member 48.

The first sidewall 431 is connected to the second sidewall 433 which is connected to the third sidewall 435 which is connected to the fourth sidewall 437 which is connected to the first sidewall 431. The first sidewall 431 is positioned opposite to the third sidewall 435, and has a sound propagation port 432 defined therein. The sound propagation port 432 is defined corresponding to the vent 232 of the casing 20. The sound propagation port 432 can be, but is not limited to, a hole, a slot, and a slit. The second and the fourth sidewalls 433, 437 are disposed opposite to each other, and both connect with the first and third sidewalls 431, 435.

The first partition wall 451 extends from a middle portion of the base wall 41, and is disposed approximately parallel with the first and the third sidewalls 431, 435. The first partition wall 451 has a communicating port 452 defined therein. The communicating port 452 is defined proximate to the base wall 41, and can be, but is not limited to, a hole, a slot, a slit, a groove, and a notch. The second and the third partition walls 453, 455 are parallel to each other and both are connected between the first partition wall 451 and the third sidewall 435. The fourth and fifth partition walls 457, 459 both are connected between the first partition wall 451 and the first sidewall 431. The partition walls 451, 453, 455, 457, 459 can be, but not limited to, planar, curved, arced, and cambered in shape.

The partition walls 451, 453, 455, 457, 459 divide a space formed between the base wall 41 and the sidewalls 431, 433, 435, 437 into four sub-chambers, i.e. a first resonance chamber 47, a second resonance chamber 48, a third chamber (not labeled) and a fourth chamber (not labeled). The first resonance chamber 47 comprises free space between the first, second and third partition walls 451, 453, 455, the third sidewall 435, and the base wall 41. The first resonance chamber 47 is configured for receiving the loudspeaker 50 therein. The second resonance chamber 49 comprises free space between the first, fourth, and fifth partition walls 451, 457, 459, the first sidewall 431, and the base wall 41. The second resonance chamber 49 communicates with the first resonance chamber 47 via the communicating port 452, and can communicate with outside via the sound propagation port 432 and the vents 232. The third chamber comprises free space between of the third and fourth partition walls 455, 457, the first, third and fourth sidewalls 431, 435, 437, and the base wall 41. The fourth chamber comprises free space between the second and fourth partition walls 453, 459, the first, second and third sidewalls 431, 433, 435, and the base wall 41. The third and fourth chambers are configured for receiving other electronic components therein.

The supporting member 48 is configured for supporting the loudspeaker 50 so as to separate the loudspeaker 50 apart from the base wall 41. The supporting member 48 includes a plurality of blocks projecting from the base wall 41, inside the first resonance chamber 47. It is to be understood that the supporting member 48 can be blocks or flange projecting from the first, second and third partition walls 451, 453, 455, and the third sidewall 435.

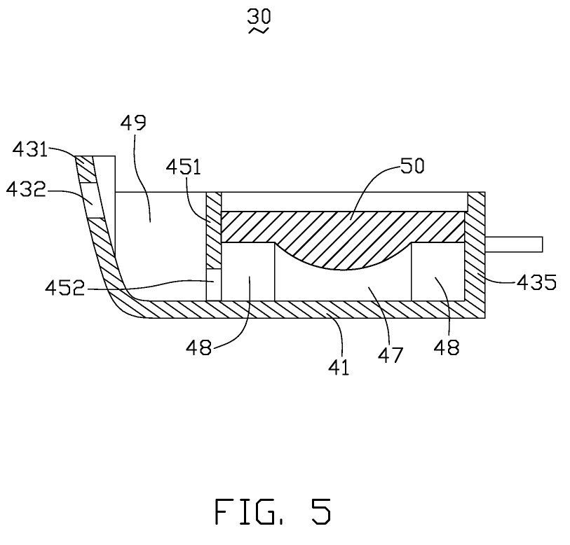

Also referring to FIG. 5, the loudspeaker 50 is configured for converting electrical signals to sound waves, and has a shape and size corresponding with that of the first resonance chamber 47 so that the loudspeaker 50 can be fittingly received in the first resonance chamber 47. The loudspeaker 50 has a sound emanating surface from which sound waves are emanated.

In assembly the speaker set 30, the loudspeaker 50 is placed inside the first resonance chamber 47 of the shell 40, and is supported and mounted on the supporting member 48. The sound emanating surface of the loudspeaker 50 faces towards the base wall 41, and is spaced a certain distance from the base wall 41. A back cover (not shown) will be provided to be mounted to the shell 40 so as to hermetically cover the first and second resonance chambers 47, 49.

The assembled shell 40 and loudspeaker 50 are arranged in the casing 20 of the mobile phone 200, with the sound propagating port 432 of the shell 40 corresponding to and communicating with the vent 232.

In use, sound waves generated by the loudspeaker 50 are transmitted to and resonate with air in the first resonance chamber 47 at the natural frequencies thereof. Sound waves in the first resonance chamber 47 are then transmitted into the second resonance chamber 49 via the communicating port 452 and further resonate with the air in the second resonance chamber 47. Finally, the sound waves are transmitted to the surrounding environment via the sound propagation port 432 of the first sidewall 431 of the shell and the vent 232 of the casing 20.

In the present mobile phone 200, the sound propagating port 432 is not aligned with the inverting port 452, causing at least some of the sound waves to reflect back and forth within the second resonance chamber 49, so that at least a portion of the sound waves that enter the second resonance chamber 49 from the first resonance chamber 47 will combine with preceding and/or succeeding sound waves in the second resonance chamber 49 to produce a better quality sound emanating from the sound propagating port 432, which increases sound quality of the mobile phone 200.

It is to be understood, however, that even though numerous characteristics and advantages of the present invention have been set forth in the foregoing description, together with details of the structure and function of the present invention, the disclosure is illustrative only, and changes may be made in detail, especially in matters of shape, size, and arrangement of parts within the principles of present invention to the full extent indicated by the broad general meaning of the terms in which the appended claims are expressed.

What is claimed is:

1. A speaker set configured for a portable electronic device, comprising:
a hollow shell comprising a first partition wall which divides an inner space of the shell into a first resonance chamber and a second resonance chamber, with the first resonance chamber acoustically communicating with the second resonance chamber via a communicating port defined in the first partition wall, and the second chamber acoustically communicating with a surrounding environment via a sound propagation port defined in the shell; and
a loudspeaker accommodated in the shell, and acoustically coupling with the first resonance chamber, so that sounds emanated from the loudspeaker can travel through the first resonance chamber, the communicating port, the second chamber and the sound propagation port and finally emit to surrounding environment.

2. The speaker set as claimed in claim 1, wherein the shell further comprises a base wall and a plurality of sidewalls surrounding a periphery of the base wall, and the first partition wall extends from a middle portion of the base wall.

3. The speaker set as claimed in claim 2, wherein the communicating port is defined proximate to the base wall.

4. The speaker set as claimed in claim 2, wherein the shell further comprises a second partition wall and a third partition wall both connecting between the first partition wall and a sidewall, so as to form the first resonance chamber therebetween.

5. The speaker set as claimed in claim 4, wherein the shell further comprise a fourth partition wall and a fifth partition wall both connecting both the first partition wall and a sidewall in which the sound propagation port is defined, so as to form the second resonance chamber therebetween.

6. The speaker set as claimed in claim 4, wherein the shell further has a supporting member disposed inside the first resonance chamber to support and separate the loudspeaker apart from the base wall.

7. A portable electronic device comprising:
a casing containing a speaker set therein and defining a vent therein, the speaker set comprising:
a hollow shell comprising a first partition wall which divides an inner space of the shell into a first resonance chamber and a second resonance chamber, with the first resonance chamber acoustically communicating with the second resonance chamber via a communicating port defined in the first partition wall, the second chamber communicating with a surrounding environment via a sound propagation port defined in the shell, and the sound propagation port being defined corresponding to the vent of the casing; and
a loudspeaker accommodated in the shell, and acoustically coupling with the first resonance chamber, so that sounds emanated from the loudspeaker can travel through the first resonance chamber, the communicating port, the second chamber, the sound propagation port, the vent and finally into surrounding environment.
